(19) United States
(12) Patent Application Publication
(10) Pub. No.: US 2007/0090478 A1
(43) Pub. Date: Apr. 26, 2007

(54) Image sensor package structure

(76) Inventors: Po-Hung Chen, Shin-Chu (TW); Mao-Jung Chen, Shin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/251,777

(22) Filed: Oct. 18, 2005

(51) Int. Cl. H01L 31/0203

(52) U.S. Cl. 257/433

(57) ABSTRACT

An image sensor package structure is proposed, in which an image sensor is fixed on a substrate having metallization traces and an adhesion layer. Electric paths of the package structure are changed from the COG (chip on glass) process to the CIS (CMOS image sensor) process to improve electric characteristics. Moreover, spacers are formed at appropriate positions to prevent glue overflow from contaminating the sensing regions and solder balls. The proposed package structure can also shrink the package area to greatly enhance the yield and quality.

### BACKGROUND OF THE INVENTION

1. Field of the Invention

The present invention relates to an image sensor package structure and, more particularly, to a CMOS image sensor (CIS) package structure.

2. Description of Related Art

Along with the popularity of audio-video multimedia, image digitization has become an inevitable trend. In recent years, products like digital still cameras (DSCs), digital video camcorders, and image scanners have been continually presented to the public, representing the advent of the era of image digitization. The CMOS technology is a very important technique in this digital era. The advantage and disadvantage, cost, humanized design of CMOS products are keys to success in fierce competitions for enterprises in this field.

FIG. 1 is a diagram of a chip-on-glass (COG) package structure of a conventional CMOS image sensor. The COG package structure comprises a light transparent substrate 10, an image sensor 16, and a glue layer 17. A metallization trace 12 and several solder balls 14 electrically connected with the metallization trace 12 are disposed on the substrate 10. The image sensor 16 includes a sensing region 18 and several pads 20. Several metal connection points 22 are disposed on the image sensor 16. The image sensor 16 is disposed on the substrate 10 via the metal connection points 22, and is electrically connected to the metallization trace 12 on the substrate 10. The glue layer 17 is located between the substrate 10 and the image sensor 16 to seal the gap between them so as to prevent outside contaminants from contaminating the sensing region 18.

For the above structure, the control of glue is difficult due to slight fluidity of glue when forming the glue layer 17. For instance, if the pads 20 on the image sensor 16 are too close to the sensing region 18, the glue will overflow to the sensing region 18 to cause malfunction of the sensing function. If the pads of the image sensor 16 are too close to the solder balls 14, the glue will flow to the region of the solder balls 14 to contaminate them. When the solder balls 14 undergo the SMT IR reflow process afterward, there will be yield loss. Moreover, the above two situations will deteriorate with the trend toward compactness of multimedia products and the shrinkage of distance between the pads 20 and the solder balls 14, hence badly affecting the process cost and the product yield.

Accordingly, the present invention provides an image sensor package structure to solve the above problems in the prior art.

### SUMMARY OF THE INVENTION

An object of the present invention is to provide an image sensor package structure, which is a CMOS image sensor (CIS) package structure. The present invention can prevent the glue layer from contaminating the solder balls and the sensing region under the trend toward to compactness of image sensor, and can also greatly enhance the package yield of image sensor.

Another object of the present invention is to provide an image sensor package structure to effectively avoid glue overflow, hence preventing outside contaminants from contaminating the sensing region.

Another object of the present invention is to provide an image sensor package structure to effectively enhance the process yield so as to reduce the production cost and improve the market competitiveness of products.

Another object of the present invention is to provide an image sensor package structure capable of shrinking the package area.

To achieve the above objects, the present invention provides an image sensor package structure, which comprises a substrate, an image sensor, and a light transparent layer. A first metallization trace is provided at the surface of the substrate. The first metallization trace has thereon several first metal connection points. The image sensor is located on the substrate. The image sensor has a sensing region and several pads. The pads have thereon several second metal connection points. A second metallization trace is disposed on the surface of the light transparent layer. The light transparent layer covers on the substrate and the image sensor. The first metallization trace, the first metal connection points, the second metallization trace, and the second metal connection points are electrically connected together.

The present invention also provides another image sensor package structure, which comprises a substrate, an image sensor, and a light transparent layer. A first metallization trace is provided at the surface of the substrate. A conductive adhesive is provided on the first metallization trace. A second metallization trace is disposed on the surface of the light transparent layer. The metallization trace has thereon several first metal connection points. The image sensor has a sensing region and several pads. The image sensor is located on the light transparent layer by bonding the several pads on the first metal connection points. The light transparent layer covers on the substrate and the image sensor. The first metallization trace, the conductive glue, the second metallization trace, and the first metal connection points are electrically connected together.

### BRIEF DESCRIPTION OF THE DRAWINGS

The various objects and advantages of the present invention will be more readily understood from the following detailed description when read in conjunction with the appended drawing, in which:

FIG. 1 is a diagram of a conventional CMOS image sensor package structure;

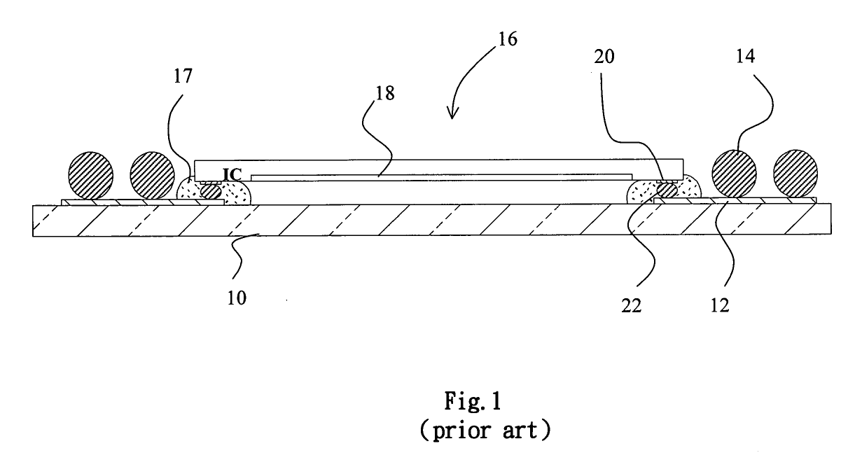

FIG. 2 is a diagram of an image sensor package structure according to an embodiment of the present invention;

FIG. 3 is a diagram of an image sensor package structure according to another embodiment of the present invention; and

FIG. 4 is a diagram of an image sensor package structure according to yet another embodiment of the present invention.

### DETAILED DESCRIPTION OF THE PREFERRED EMBODIMENTS

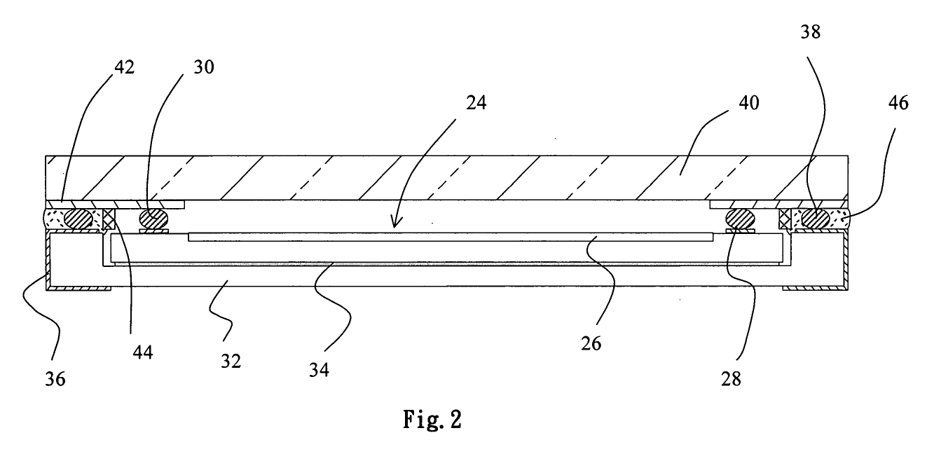

FIG. 2 is a diagram of an image sensor package structure according to an embodiment of the present invention. The image sensor package structure comprises an image sensor 24, a substrate 32, a light transparent layer 40, a spacer 44, and a glue layer 46. The image sensor 24 includes a sensing region 26 and several pads 28. The pads 28 have several metal connection points 30. An adhesion layer 34 adhere the image sensor 24 to the substrate 32. A metallization trace 36 is disposed at the surface of the substrate 32. Several metal connection points 38 are provided on the metallization trace 36. The light transparent layer 40 covers the image sensor 24 and the substrate 32. The light transparent layer 40 can be a light transparent glass capable of filtering out a certain light wavelength. A metallization trace 42 is disposed on the light transparent layer 40. The metal connection points 30, the metallization trace 42, the metal connection points 38, and the metallization trace 36 are electrically connected together. The spacer 44 is located on the metallization trace 42 of the light transparent layer 40 and is close to the sensing region 26 at the inside of the metal connection points 38. The glue layer 46 is used to seal the gap between the light transparent layer 40 and the substrate 32. The spacer 44 can be formed by means of screen printing, and its material can be insulating polymer having slight elasticity like polyimide.

According to the structure of this embodiment, the present invention has the following characteristics:
1. The metallization trace on the substrate can be used to facilitate electric connection with the PCB.
2. The problem that the glue layer contaminates the solder balls won't arise.
3. Through the use of the spacer, the range of glue overflow can be effectively confined to prevent glue overflow from contaminating the sensing region and also accomplish the object of shrinking the package area.
4. The conventional COG package structure having lower yields is abandoned, and the CIS package structure having higher yields is adopted.

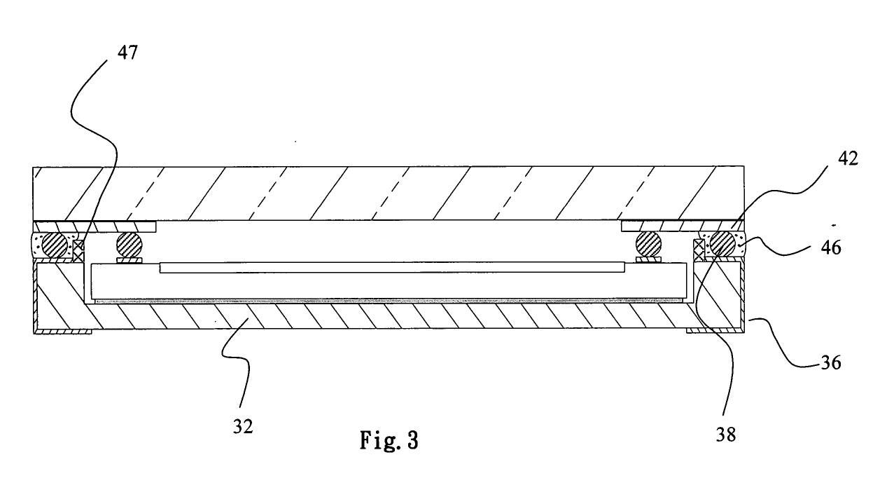

FIG. 3 is a diagram of an image sensor package structure according to another embodiment of the present invention, in which the position of the spacer 47 is changed to be located on the substrate 32 to avoid the overflow contamination of the glue layer 46.

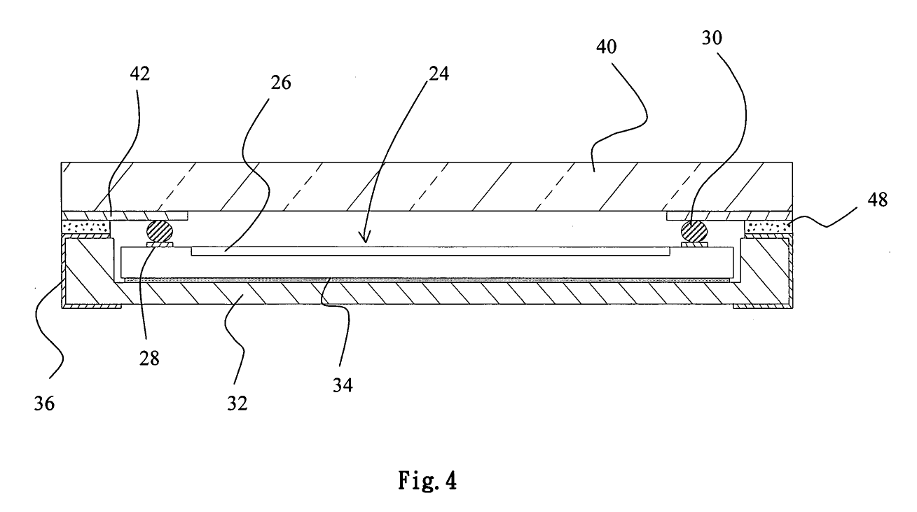

FIG. 4 is a diagram of an image sensor package structure according to yet another embodiment of the present invention. The package structure comprises a substrate 32, an image sensor 24, and a light transparent layer 40. The substrate 32 has an adhesion layer 34 thereon. A metallization trace 36 is disposed at the surface of the substrate 32. An anisotropic conductive film (ACF) 48 is adhered to the metallization trace 36. The adhesion layer 34 adheres the image sensor 24 to the substrate 32. The image sensor 24 includes a sensing region 26 and several pads 28. Several metal connection points 30 are provided on the pads 28. The light transparent layer 40 covers on the substrate 32 and the image sensor 24. A metallization trace 42 is disposed on the light transparent layer 40. The metal connection points 30, the metallization trace 42, the ACF 48, and the metallization trace 36 are electrically connected together.

This embodiment differs from the above embodiments in that the ACF is used to achieve electric connection and also prevent outside contaminants from contaminating the sensing region.

To sum up, the present invention abandons the conventional COG package structure and adopts a novel COG package structure to prevent outside contaminants or glue overflow from affecting the sensing region and the solder balls, thereby ensuring the yield and normal operation of device. Furthermore, under the trend toward compactness of device, the present invention effectively solves the problem of glue overflow that otherwise cannot be worked out using existent techniques.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. An image sensor package structure comprising:
a substrate having a first metallization trace at the surface thereof, said first metallization trace having thereon several first metal connection points;
an image sensor located on said substrate, said image sensor having a sensing region and several pads, said pads having thereon several second metal connection points; and
a light transparent layer having a second metallization trace on a surface thereof, said light transparent layer covering on said substrate and said image sensor, said first metallization trace, said first metal connection points, said second metallization trace, and said second metal connection points being electrically connected together.

2. The image sensor package structure as claimed in claim 1, further comprising a spacer, wherein said spacer is located between said first metal connection points and said sensing region of said image sensor.

3. The image sensor package structure as claimed in claim 1, further comprising an adhesion layer, wherein said adhesion layer is located on said substrate and used to adhere said image sensor to said substrate.

4. The image sensor package structure as claimed in claim 1, further comprising a glue layer, wherein said glue layer is located between said light transparent layer and said substrate and used to seal a gap between said light transparent layer and said substrate.

5. The image sensor package structure as claimed in claim 1, wherein said light transparent layer is a glass.

6. The image sensor package structure as claimed in claim 1, wherein said light transparent layer can filter out a certain light wavelength.

7. The image sensor package structure as claimed in claim 1, wherein a spacer corresponding to a position between said first metal connection points and said second metal connection points is formed on said second metallization trace.

8. The image sensor package structure as claimed in claim 1, wherein a spacer corresponding to a position between said first metal connection points and said second metal connection points is formed on said substrate.

9. An image sensor package structure comprising:
a substrate having a first metallization trace at the surface thereof, a conductive adhesive being provided on said first metallization trace;
an image sensor located on said substrate, said image sensor having a sensing region and several pads, said pads having thereon several first metal connection points; and
a light transparent layer having a second metallization trace on a surface thereof, said light transparent layer covering on said substrate and said image sensor, said first metallization trace, said conductive glue, said second metallization trace, and said first metal connection points being electrically connected together.

10. The image sensor package structure as claimed in claim 9, wherein said conductive adhesive is an anisotropic conductive film.

11. The image sensor package structure as claimed in claim 9, wherein said light transparent layer can filter out a certain light wavelength.

12. The image sensor package structure as claimed in claim 9, further comprising an adhesion layer, wherein said adhesion layer is used to adhere said image sensor to said substrate.
